(19) United States
(12) Patent Application Publication
(10) Pub. No.: US 2026/0344085 A1
(43) Pub. Date: Oct. 29, 2026

(54) IMAGE SENSOR DEVICE AND MANUFACTURING METHOD THEREOF

(71) Applicant: Taiwan Semiconductor Manufacturing Company, Ltd., Hsinchu (TW)

(72) Inventors: Ming-Yu Kuo, Tainan City (TW); Hung-Chang Chang, Tainan City (TW); Jiech-Fun Lu, Tainan County (TW)

(73) Assignee: Taiwan Semiconductor Manufacturing Company, Ltd., Hsinchu (TW)

(21) Appl. No.: 19/190,747

(22) Filed: Apr. 27, 2025

(51) Int. Cl. H10F 39/00

(52) U.S. Cl. CPC H10F 39/807; H10F 39/014; H10F 39/028; H10F 39/811

(57) ABSTRACT

An image sensor device includes a substrate, photodetectors, and a backside deep trench isolation (BDTI) structure. The substrate includes a front side, a back side opposite to the front side, and pixel regions disposed between the front side and the back side and arranged in an array. One of the pixel regions includes an angular corner protruding toward a diagonal one of the pixel regions in a top plan view. The photodetectors are disposed in the pixel regions, and the BDTI structure extends from the back side of the substrate and surrounds the respective pixel region.

### BACKGROUND

Many modern-day electronic devices (e.g., smartphones, digital cameras, biomedical imaging devices, automotive imaging devices, etc.) include image sensor devices for capturing images. The respective image sensor device includes photodetectors configured to absorb incident radiation and output electrical signals corresponding to the incident radiation. The photodetectors are often spaced from one another by a deep trench isolation structure. Although existing image sensor devices have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-3A, 4A, 5A, and 6 are schematic cross-sectional views of various stages of manufacturing an image sensor device, in accordance with some embodiments.

FIG. 3B is a schematic top plan view of FIG. 3A, in accordance with some embodiments.

FIG. 3C is a schematic cross-sectional view of a variation of FIG. 3A, in accordance with alternative embodiments.

FIG. 4B is a schematic top plan view of the structure taken along line A-A′ shown in FIG. 4A, in accordance with some embodiments.

FIG. 5B is a schematic profile showing the variation of critical dimensions at different positions between adjacent pixel regions, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Photodetectors are often separated by trench isolation structures. For example, backside deep trench isolation (BDTI) structures electrically and/or optically isolate the pixel regions within which the photodetectors are disposed. However, an etch rate for etching the BDTI structures at a cross-road region of the substrate may be greater relative to other areas of the BDTI structures due to the increased critical dimensions between the pixel regions, where the cross-road region is a region disposed among at least four of the pixel regions. The increased critical dimensions may result in increased trench depth loading. In some cases, the floating diffusion region in the cross-road region may be damaged during the formation of trench for the BDTI structures because of the increased trench depth loading that occurs when the BDTI structures are formed. The damaged floating diffusion region may negatively affect the performance of the resulting image sensor device. Therefore, the critical dimension of the trench for the BDTI structures in the cross-road region should be reduced to prevent trench depth loading. In addition, a number of factors to the trenches to be formed may influence the etch depth and other process characteristics. The effects may be grouped in wafer-to-wafer effects (e.g., macro-loading effects) and within-wafer effects (e.g., micro-loading effects which include aspect ratio dependent etching). In general, the trench having larger critical dimension (e.g., in the cross-road region) may have greater etch depth than the trench having smaller critical dimension (e.g., in the pixel region). There is a need to develop a different approach of forming the trench for the BDTI structures in order to achieve within-in-wafer and wafer-to-wafer uniformity.

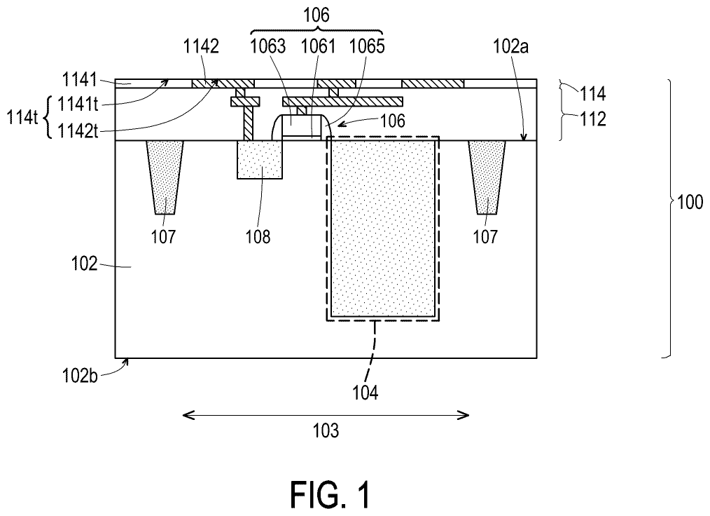

FIGS. 1-6 are schematic views of various stages of manufacturing an image sensor device, in accordance with some embodiments. Referring to FIG. 1, a first tier 100 is provided. For example, the first tier 100 includes at least one photodetector 104 formed in a substrate 102. The substrate 102 may include a semiconductor substrate (e.g., silicon substrate, SiGe substrate, GaAs substrate, etc.), a silicon-on-insulator (SOI) substrate, or some other semiconductor substrate that is capable of generating a charge from photons of incident light. In some embodiments, the substrate 102 includes a semiconductor wafer or one or more die on a wafer, as well as any other type of semiconductor and/or epitaxial layers formed thereon and/or otherwise associated therewith.

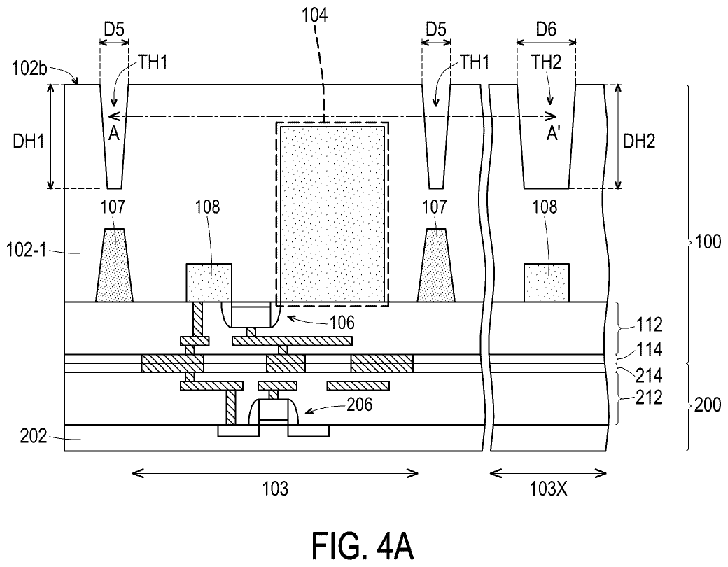

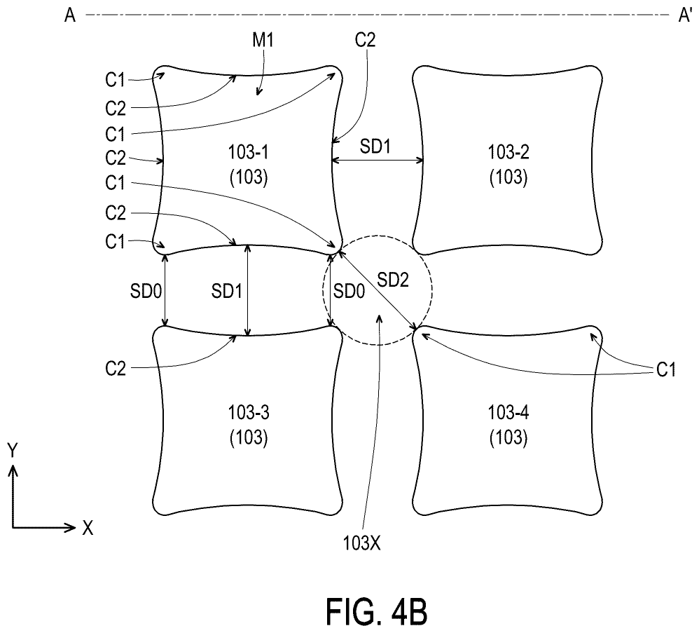

The substrate 102 may include at least one pixel region 103 disposed within the substrate 102. In some embodiments, a plurality of pixel region 103 is arranged in an array including rows and/or columns (see FIG. 4B). The term “pixel” may refer to a unit cell containing features (e.g., a photodetector and associated circuitries) for converting electromagnetic radiation to electrical signal. Each pixel may include a photodetector for recording an intensity or brightness of light and transistors (e.g., a transfer transistor, a reset transistor, a source-follower transistor, a select transistor, another suitable transistor, or combinations thereof). The circuitry (e.g., readout circuitry, control circuitry, etc.) may be coupled to the pixel array to provide an operating environment for the pixels and support external communications with the pixels.

In some embodiments, the photodetector 104 is formed in the pixel region 103. The photodetector 104 may include a photodiode, a complimentary metal-oxide-semiconductor (CMOS) image sensor, a charged coupling device (CCD) sensor, an active sensor, a passive sensor, and/or other sensor. The pixel region 103 may be designed having various sensor types. The photodetector 104 may include one or more doped layer(s) and is configured to absorb photons of incident light. For example, the absorption of photons causes the photodetector 104 to accumulate a charge (referred to as a photocurrent) due to the photoelectric effect, and the photons may bombard the photodetector 104 to cause emission of electrons in the photodetector 104. Although one photodetector 104 and one pixel region 103 is shown herein, a plurality of photodetectors 104 may be formed in the pixel regions 103 and arranged in an array.

In some embodiments, the first tier 100 includes at least one transfer gate 106 formed on a front side 102a of the substrate 102. For example, the transfer gate 106 includes a gate dielectric layer 1061 disposed on the front side 102a of the substrate 102, a gate electrode layer 1063 formed on the gate dielectric layer 1061, and sidewall spacers 1065 formed on opposing sides of the gate electrode layer 1063 and opposing sidewalls of the gate dielectric layer 1061. In some embodiments, one or more floating diffusion region(s) 108 is formed in the substrate 102 and in proximity to the photodetector 104. The transfer gate 106 may be laterally between the photodetector 104 and the floating diffusion region 108. For example, the transfer gate 106 is configured to transfer the accumulated charge from the photodetector 104 to the floating diffusion region 108 during the operation.

With continued reference to FIG. 1, the first tier 100 may include one or more shallow trench isolation (STI) structure(s) 107 formed in the substrate 102 and extending from the front side 102a of the substrate 102. For example, the STI structure 107 is adjacent to, and at least partially surrounds, the photodetector 104. In some embodiments, the STI structure 107 is disposed on opposing sides of the pixel region 103 and is configured to provide isolation between adjacent pixel regions. The STI structure 107 may include one or more dielectric materials (e.g., silicon oxide) formed in the shallow trenches in the front side 102a of the substrate 102.

With continued reference to FIG. 1, the first tier 100 may include an interconnect structure 112 formed over the front side 102a of the substrate 102. For example, the interconnect structure 112 includes an interlayer dielectric (ILD) layer 1121 and conductive features 1122 formed in the ILD layer 1121. In some embodiments, the ILD layer 1121 includes an oxide, a nitride, a combination thereof, or other suitable dielectric material(s). The conductive features 1122 may include conductive lines, conductive vias, contact pads, etc. For example, a first conductive via of the conductive features 1122 extends from the gate electrode layer 1063 of the respective transfer gate 106 to another one of conductive features 1122. In some embodiments, a second conductive via of the conductive features 1122 extends from the floating diffusion region 108 to another one of conductive features 1122.

Still referring to FIG. 1, the first tier 100 may include a bonding structure 114 formed over the interconnect structure 112. For example, the bonding structure 114 includes a bonding dielectric layer 1141 and bonding features 1142 laterally covered by the bonding dielectric layer 1141. In some embodiments, the bonding dielectric layer 1141 includes an oxide or other suitable bonding material(s). The respective bonding feature 1142 may be formed in a pad form, a via form, or a combination thereof, etc. The bonding features 1142 may be electrically coupled to the transfer gate 106 through the conductive features 1122 of the interconnect structure 112. In some embodiments, a top surface 1141t of the bonding dielectric layer 1141 is substantially leveled with top surfaces 1142t of the bonding features 1142, within process variations. The top surface 1141t of the bonding dielectric layer 1141 and the top surfaces 1142t of the bonding features 1142 may be collectively viewed as a bonding surface 114t of the first tier 100. In some embodiments, the bonding surface 114t is substantially flat by performing a planarization process (e.g., chemical mechanical polishing, grinding, etching, a combination thereof, etc.) on the bonding structure 114.

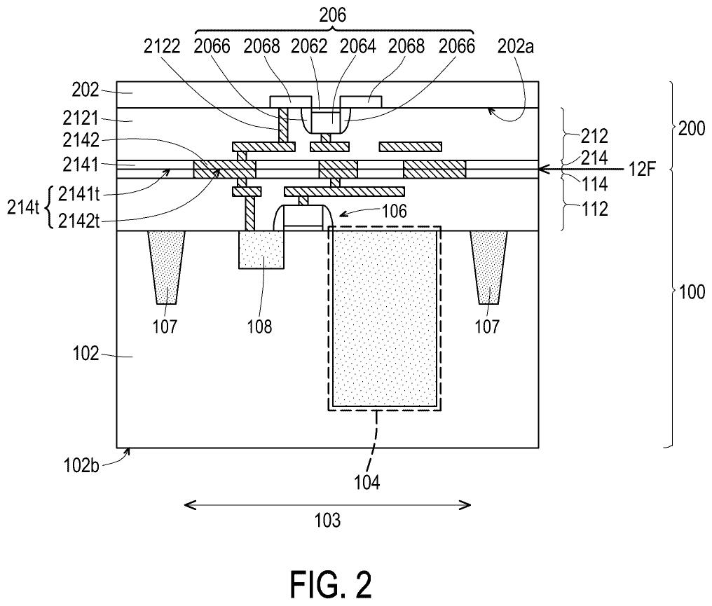

Referring to FIG. 2 and with reference to FIG. 1, a second tier 200 may be provided. For example, the second tier 200 includes a substrate 202 and one or more transistor(s) 206 formed in/on a front side 202a of the substrate 202. For example, the substrate 202 includes a bulk silicon substrate, a silicon-on-insulator (SOI) substrate, or another suitable semiconductor substrate. The transistor 206 may include a pair of source/drain (S/D) regions 2068 formed in the substrate 202, a gate dielectric layer 2062 formed over the front-side 202a of the substrate 202, and a gate electrode layer 2064 formed on the gate dielectric layer 2062. In some embodiments, sidewall spacers 2066 are formed on opposing sides of the gate electrode layer 2064 and opposing sidewalls of the gate dielectric layer 2062.

With continued reference to FIG. 2, the second tier 200 may include an interconnect structure 212 formed over the front side 202a of the substrate 202. For example, the interconnect structure 212 includes an ILD layer 2121 and conductive features 2122 formed in the ILD layer 2121. In some embodiments, the ILD layer 2121 includes an oxide, a nitride, a combination thereof, or other suitable dielectric material(s). The conductive features 2122 may include conductive lines, conductive vias, contact pads, etc. For example, a first conductive via of the conductive features 2122 extends from the gate electrode layer 2064 of the transistor 206 to another one of conductive features 2122. In some embodiments, a second conductive via of the conductive features 2122 extends from the S/D region 2068 of the respective transistor 206 to another one of conductive features 2122.

With continued reference to FIG. 2, the second tier 200 may include a bonding structure 214 formed on the interconnect structure 212 and electrically coupled to the transistor(s) 206 through the interconnect structure 212. For example, the bonding structure 214 includes a bonding dielectric layer 2141 and bonding features 2142 laterally covered by the bonding dielectric layer 2141. In some embodiments, the bonding dielectric layer 2141 includes an oxide or other suitable bonding material(s). The respective bonding feature 2142 may be formed in a pad form, a via form, or a combination thereof, etc. The bonding features 2142 may be electrically coupled to the transistor(s) 206 through the conductive features 2122 of the interconnect structure 212. In some embodiments, a top surface 2141t of the bonding dielectric layer 2141 is substantially leveled with top surfaces 2142t of the bonding features 2142, within process variations. The top surface 2141t of the bonding dielectric layer 2141 and the top surfaces 2142t of the bonding features 2142 may be collectively viewed as a bonding surface 214t of the second tier 200. In some embodiments, the bonding surface 214t is substantially flat by performing the planarization process on the bonding structure 214.

Still referring to FIG. 2 and FIG. 1, the second tier 200 may be bonded to the first tier 100. For example, the bonding structure 214 of the second tier 200 is bonded to the bonding structure 114 of the first tier 100. The bonding of the second tier 200 to the first tier 100 may involve dielectric-to-dielectric (e.g., oxide-to-oxide) bonding and metal-to-metal (e.g., copper-to-copper) bonding. For example, the bonding dielectric layer 2141 is fused to the bonding dielectric layer 1141, and the bonding features 2142 are bonded to the bonding features 1142 with one-to-one correspondence. The transistor(s) 206 included in the second tier 200 may be electrically coupled to the first tier 100 through the bonding structures 214 and 114. In some embodiments, the bonding interface 12F of the first tier 100 and the second tier 200 is substantially flat, within process variations. In some embodiments, the second tier 200 is an application-specific integrated circuit (ASIC) configured to process electrical signals received from the first tier 100.

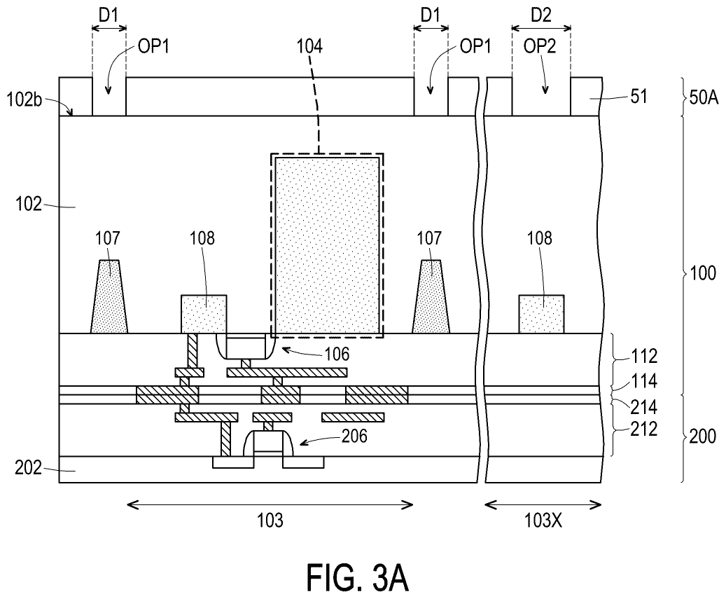

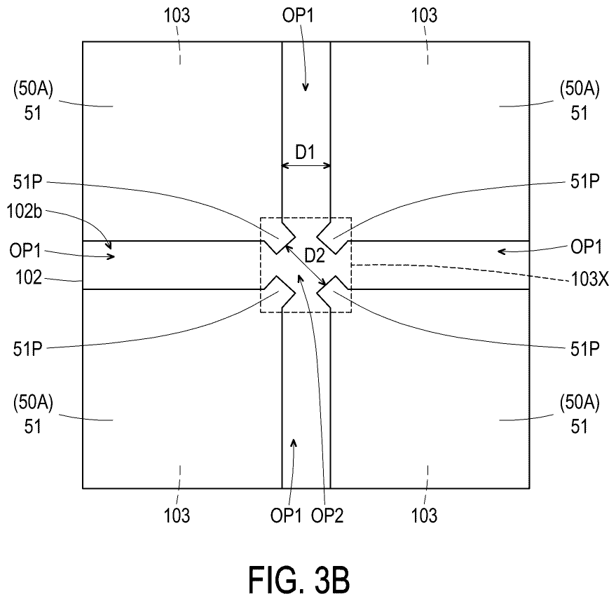

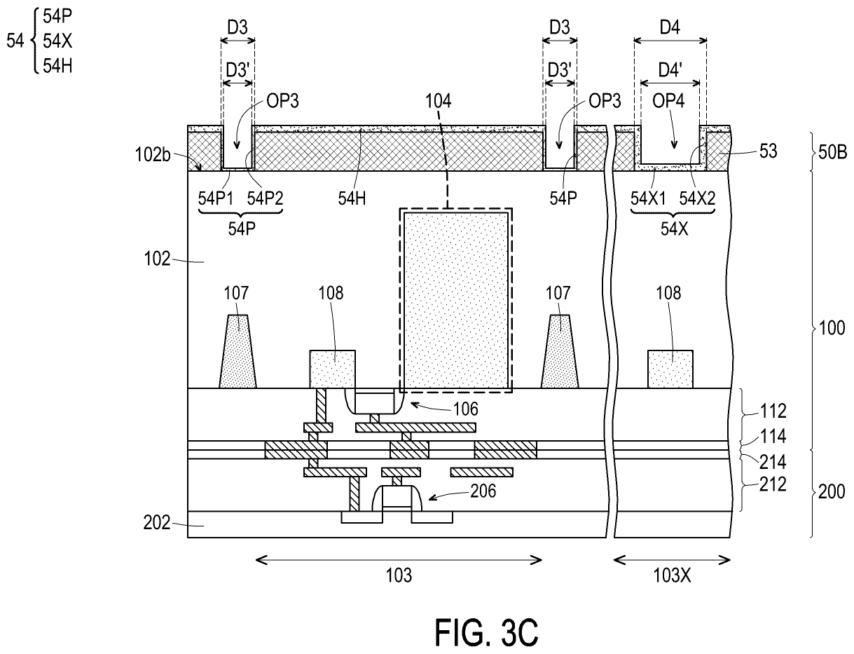

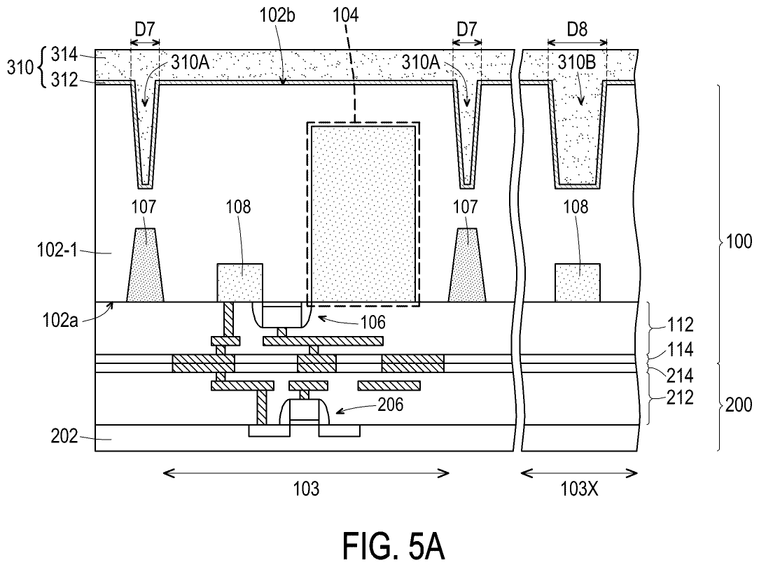

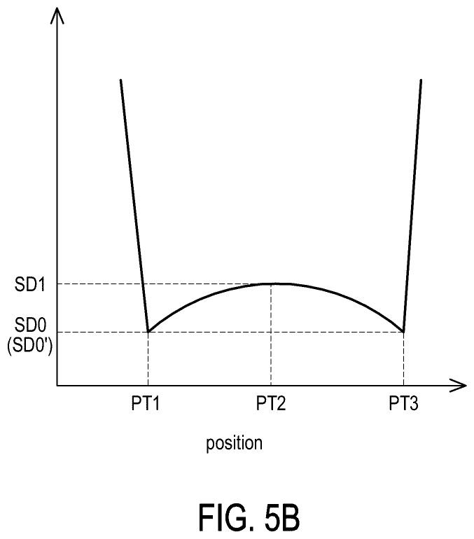

After bonding the second tier 200 to the first tier 100, a trench may be formed in the substrate 102 to encircle the respective pixel regions 103 (see FIG. 4B), and then deep trench isolation (DTI) structure may be formed in the trench (see FIG. 5A). For example, the trench is both along the X-direction of the array of the pixel regions 103 and along the Y-direction of the array of the pixel regions 103. Accordingly, the dimension of the trench may be widest at the cross-road region of the array of the pixel regions 103. The widest dimension of the trench at the cross-road region may result from greater diagonal spacing at the cross-road region between diagonal ones of the pixel regions relative to lateral spacing between adjacent ones of the pixel regions. The greater spacing at the cross-road region may result in increased trench depth loading. For example, an etch rate for etching the trench is greater at the cross-road region than in other regions of the trench due to the trench having the greater critical dimension at the cross-road region. In some cases, the floating diffusion region located within the cross-road region may be damaged during the formation of the trench because of the increased trench depth loading. The damaged floating diffusion region may cause electrical leakage and may negatively affect the performance of the image sensor device. FIGS. 3A and 3C show different approaches for forming trenches in the substrate 102 for accommodating the DTI structure therein. For example, FIGS. 3A-3B show an approach using optical proximity correction (OPC) to compensate the increased critical dimension associated with the loading effect. FIG. 3C shows an approach using a modified mask to reduce the lateral dimension and the depth of the trench formed in the cross-road region.

Referring first to FIG. 3A and with reference to FIG. 2, a patterned mask 50A may be formed on a back side 102b of the substrate 102. In some embodiments, the patterned mask 50A is a photoresist or includes any suitable photo-sensitive material(s). For example, the patterned mask 50A includes first openings OP1 and a second opening OP2. The first openings OP1 may be formed over the boundary of the pixel region 103. For example, the first openings OP1 are formed directly over the STI structure 107. The second opening OP2 may be formed within the cross-road region 103X. The floating diffusion region 108 may be disposed within the cross-road region 103X. For example, the second opening OP2 is formed directly over the floating diffusion region 108. In some embodiments, a lateral dimension D1 of the respective first opening OP1 is less than a lateral dimension D2 of the second opening OP2.

FIG. 3B is a schematic top plan view showing the patterned mask 50A and the underlying substrate 102 of FIG. 3A. As shown in FIG. 3B, the cross-road region 103X is a region disposed among four of the pixel regions 103 which are arranged in an array. The first openings OP1 may surround the boundary of the respective pixel region 103 and may be in communication with one another through the second opening OP2, in the top plan view. The patterned mask 50A may include a plurality of masking portions 51, and each of the masking portions 51 may cover one of the pixel regions 103. The first openings OP1 may be formed around each side of the respective masking portion 51.

In some embodiments, the respective masking portion 51 of the patterned mask 50A has a protrusion 51P extending form the respective pixel region 103 into the cross-road region 103X. For example, the protrusion 51P of one of the masking portions 51 diagonally extends toward the diagonal one of the masking portions 51. The protrusion 51P of the masking portions 51 may be separated from one another by the second opening OP2. The lateral dimension D2 of the second opening OP2 may be the diagonal spacing in the cross-road region between the diagonal ones of the pixel regions 103 as shown in the top plan view. The protrusions 51P may be viewed as assist portions for compensating the size of the second opening OP2. The adjustment of the patterned mask (e.g., the protrusions 51P of the patterned mask 50) may be viewed as the shape correction which includes critical dimension modification associated with the loading effect. For example, the lateral dimension D2 of the second opening OP2 is reduced to a smaller lateral dimension by using the shape correction. In some embodiments, the shape correction is referred to as optical proximity correction (OPC) control.

As mentioned in the preceding paragraphs, an etch rate for forming the trench within the cross-road region 103X may be greater than an etch rate for forming the trench along the pixel regions 103 due to the larger size of the trench formed within the cross-road region 103X. By forming the pattern mask 50A with the protrusions 51P extending into the cross-road region 103X, the lateral (or diagonal) dimension D2 of the second opening OP2 may be reduced, as compared to some cases using the pattern mask without protrusions extending into the cross-road region. The etch rate for forming the trench within the cross-road region 103X may be adjusted during the subsequently-performed patterning process (see FIG. 4A), so that the floating diffusion region 108 within the cross-road region 103X may be protected from being etched during the subsequently-performed etching process for forming the trench. This may prevent electrical leakage and improve performance of the pixel array.

Next, referring to FIG. 3C and with reference to FIG. 3A, a patterned mask 50B may be formed on the back side 102b of the substrate 102. The patterned mask 50B is similar to the patterned mask 50A described in FIGS. 3A-3B, only the difference is detailed. For example, the patterned mask 50B includes a first layer 53 and a second layer 54 lining the first layer 53. In some embodiments, the first layer 53 is a photoresist or any suitable photo-sensitive material(s). The second layer 54 may include any suitable polymeric material(s). The first layer 53 and the second layer 54 may be made of different materials. In some embodiments, the first layer 53 is a patterned layer and includes first openings OP3 and a second opening OP4. Portions of the back side 102b of the substrate 102 may be exposed by the first openings OP3 and the second opening OP4. The first openings OP3 may be formed over the boundary of the pixel region 103. For example, the first openings OP3 are formed directly over the STI structure 107. The second opening OP4 may be formed over the cross-road region 103X. For example, the second opening OP4 is directly over the floating diffusion region 108. In some embodiments, a lateral dimension D3 of the respective first opening OP3 is less than a lateral dimension D4 of the second opening OP4.

With continued reference to FIG. 3C, each of the first openings OP3 and the second opening OP4 may be lined with the second layer 54. For example, the second layer 54 includes a first portion 54P lining the respective first opening OP3, a second portion 54X lining the second opening OP4, and a third portion 54H connected to the first portion 54P and the second portion 54X. The second portion 54X may be thicker than the first portion 54P. In some embodiments where the second layer 54 is deposited with the use of plasma, radicals in the plasma may more easily diffuse into the second opening OP4 due to the larger size of the second opening OP4. This may render the second portion 54X formed in the second opening OP4 thicker than the first portion 54P formed in the first opening OP3. In some embodiments, the first portion 54P and the second portion 54X respectively include horizontal segments 54P1 and 54X1 directly overlying the back side 102b of the substrate 102, and respectively include vertical segments 54P2 and 54X2 connected to the corresponding horizontal segments 54P1 and 54X1 and lining the inner sidewalls of the first layer 53.

With continued reference to FIG. 3C, a lateral distance D3′ between the vertical segments 54P2 formed in the respective first opening OP3 may be less than a lateral distance D4′ between the vertical segments 54X2 formed in the second opening OP4. The lateral distance D3′ may be less than the lateral dimension D3, while the lateral distance D4′ may be less than the lateral dimension D4. The first layer 53 may have a first ratio of the lateral dimension D4 to the lateral dimension D3. The second layer 54 may have a second ratio of the lateral distance D4′ to the lateral distance D3′. In some embodiments, the second ratio is less than the first ratio.

As mentioned in the preceding paragraphs, an etch rate for forming the trench within the cross-road region 103X may be greater than an etch rate for forming the trench along the pixel regions 103 due to the larger size of the trench formed within the cross-road region 103X. By forming the second layer 54 lining the openings of the first layer 53, the critical dimension of the openings (e.g., OP3 and OP4) may be adjusted by the second layer 54. For example, the thicker portion of the second layer 54 is formed in the second opening OP4 so that the opening size of the patterned mask 50B in the cross-road region 103X is reduced, as compared with the masks without the of the second layer 54 in some cases. Although the opening size of the patterned mask 50B in the pixel region 103 is also reduced due to the first portion 54P of the second layer 54 formed in the respective first opening OP3, the first portion 54P is thinner than the second portion 54X, so that the ratio of the adjustment of the opening size in the pixel region 103 may be less than the ratio of the adjustment of the opening size in the cross-road region 103X. The etch rate for forming the trench within the cross-road region 103X may be adjusted during the subsequently-performed patterning process (see FIG. 4A), so that the floating diffusion region 108 within the cross-road region 103X may be protected from over-etching. This may prevent electrical leakage and improve performance of the pixel array.

Referring to FIG. 4A and with reference to FIG. 3A and FIG. 3C, a patterning process may be performed to partially remove the substrate 102 by using the patterned mask (e.g., 50A or 50B) to form a substrate 102-1 including first trenches TH1 and a second trench TH2. The first trenches TH1 may be formed along the pixel region 103 and the second trench TH2 may be formed within the cross-road region 103X. The patterning process may include one or more etching process or other suitable removal process. The patterned mask (e.g., 50A or 50B) may act as an etch mask. In some embodiments, a plasma etching process is performed to etch the first trenches TH1 and the second trench TH2, in which ions in a plasma are used to bombard the first trenches TH1 and the second trench TH2 to remove material to perform the etch.

In some embodiments, a lateral dimension D5 of the respective first trench TH1 along the pixel region 103 is less than a lateral dimension D6 of the second trench TH2 in the cross-road region 103X. The second trench TH2 may have a depth DH2 greater than a depth DH1 of the respective first trench TH1. It is appreciated that for the trenches having greater critical dimensions, radicals in the plasma may more easily diffuse into the trench sidewalls and bottom surface. By adjusting the critical dimensions of the trenches, a ratio of the etch depth in the cross-road region to the etch depth along the pixel region may be, for example, close to 1. The floating diffusion region 108 is located within the cross-road region 103X may not be damaged during etching because of the adjustment of the trench depth of the second trench TH2.

In some embodiments where the patterned mask 50A described in FIG. 3A is used, during the patterning process, a portion of the substrate 102 along the pixel region 103 is etched through the first openings OP1 to form the first trenches TH1, while another portion of the substrate 102 in the cross-road region 103X is etched through the second openings OP2 to form the second trench TH2. In some embodiments where the patterned mask 50B described in FIG. 3C is used, during the patterning process, the horizontal segments 54P1 of the first portion 54P along the pixel region 103 and the horizontal segments 54X1 of the second portion 54X in the cross-road region 103X are etched to expose portions of the back side 102b of the substrate 102. As the etching continues, the portions of the back side 102b of the substrate 102 may be etched to form the first trenches TH1 along the pixel region 103 and the second trench TH2 in the cross-road region 103X.

As mentioned in the preceding paragraphs, by adjusting the opening size of the patterned mask in the cross-road region 103X, the difference between the etch rates for forming the first trenches TH1 along the pixel region 103 and the second trench TH2 in the cross-road region 103X may be reduced. The etch depth of the second trench TH2 in the cross-road region 103X may be controlled, so that the floating diffusion region 108 within the cross-road region 103X is protected from over-etching during the patterning of the substrate. This may prevent electrical leakage and improve performance of the pixel array. As shown in FIG. 4A, the respective first trench TH1 may be right above the STI structure 107, while the second trench TH2 may be right above the floating diffusion region 108. In some embodiments, the STI structure 107 is tapered in a direction from the front side 102a toward the back side 102b, while the first trenches TH1 and the second trench TH2 are respectively tapered in an opposing direction. For example, the first trenches TH1 and the second trench TH2 may be respectively tapered from the back side 102b toward the front side 102a of the substrate 102-1.

FIG. 4B is a schematic top plan view of the structure taken along the reference cross section A-A′ of FIG. 4A. Referring to FIG. 4B and FIG. 4A, the first trenches TH1 formed at a boundary of the pixel region 103 may be in communication with the second trench TH2 formed in the cross-road region 103X to separate the pixel regions (e.g., 103-1, 103-2, 103-3, and 103-4) of the substrate 102-1 from one another, in the top plan view. The pixel regions (e.g., 103-1, 103-2, 103-3, and 103-4) may be arranged in an array including rows and/or columns in the top plan view, and may be referred to as a pixel array. In some embodiments, the respective pixel region 103 has a petal-like top-view shape. For example, the respective pixel region 103 includes four angular corners C1. The respective angular corners C1 may be a convex corner. For example, the respective angular corners C1 protrudes outward somewhat from the main area M1 of the pixel region 103 toward the cross-road region 103X in the top plan view. In some embodiments, the angular corners C1 are rounded outwardly-protruding corners. For example, the right lower angular corner C1 of the pixel region 103-1 is protruded toward the left upper angular corner C1 of the pixel region 103-4, where the pixel regions 103-1 and 103-4 are diagonally arranged. A maximum diagonal spacing SD2 may be measured between the right lower angular corner C1 of the pixel region 103-1 and the left upper angular corner C1 of the pixel region 103-4.

With continued reference to the top plan view of FIG. 4B, the respective pixel region 103 may include four sides C2 connected to the angular corners C1. In some embodiments, the respective side C2 is a concave curve toward the main area M1. For example, a maximum spacing SD1 is measured along the Y-direction and between the lower side C2 of the pixel region 103-1 and the upper side C2 of the adjacent pixel region 103-3, or a maximum spacing SD1 is measured along the X-direction and between the right side C2 of the pixel region 103-1 and the left side C2 of the adjacent pixel region 103-2. In some embodiments, the maximum diagonal spacing SD2 is greater than the maximum spacing SD1. For example, a ratio of the maximum diagonal spacing SD2 to the maximum spacing SD1 is less than 2.

Referring to FIG. 5A and with reference to FIG. 4A, the first trenches TH1 and the second trench TH2 may be filled with one or more dielectric layer(s) to form a DTI structure 310. Since the DTI structure 310 extends from the back side 102b of the substrate 102-1, the DTI structure 310 may be referred to as a backside DTI (BDTI) structure 310. In some embodiments, the DTI structure 310 is disposed at the boundary of the pixel region 103 and may be referred to a boundary DTI (BDTI) structure 310. For example, the BDTI structure 310 includes a liner layer 312 and a filling dielectric layer 314 overlying the liner layer 312. In some embodiments, the liner layer 312 includes an oxide, a metal oxide, and/or the like. In some embodiments, the filling dielectric layer 314 includes an oxide, a nitride, carbide, or a mixture thereof, or another type of dielectric material is used in place of the filling dielectric layer 314. For example, the first trenches TH1 and the second trench TH2 are each lined with the liner layer 312, and the filling dielectric layer 314 fills the rest space of the first trenches TH1 and the second trench TH2. The liner layer 312 may further extend to cover the back side 102b of the substrate 102-1, and the filling dielectric layer 314 may extend to form over the back side 102b of the substrate 102-1. In some embodiments, the liner layer 312 is configured to increase reflectivity of the BDTI structure 310. The filling dielectric layer 314 may function to reflect incident light toward the photodetector 104 to increase the quantum efficiency of the resulting device and to reduce optical crosstalk between the pixels.

With continued reference to FIG. 5A and FIG. 4A, the BDTI structure 310 may include first portions 310A formed in the first trenches TH1 along the pixel region 103 and a second portion 310B formed in the second trench TH2 in the cross-road region 103X. The first portions 310A may be formed directly over the STI structure 107 and the second portion 310B may be formed directly over the floating diffusion region 108. In some embodiments, the STI structure 107 is tapered in a direction from the front side 102a of the substrate 102-1 toward the back side 102b of the substrate 102-1, while the first portions 310A and the second portion 310B are respectively tapered in a direction opposite to the tapering direction of the STI structure 107. For example, the first portions 310A and the second portion 310B are respectively tapered from the back side 102b toward the front side 102a of the substrate 102-1. In some embodiments, a lateral dimension D7 of the respective first portion 310A formed along the pixel region 103 is less than a lateral dimension D8 of the second portion 310B formed in the cross-road region 103X.

FIG. 5B schematically illustrates a profile of the variation of critical dimensions at different positions between adjacent ones of the pixel regions 103, in accordance with some embodiments. Referring to FIG. 5B and with reference to FIG. 4B, the X-axis represents the position of the respective first portion 310A formed in the first trench TH1, and the Y-axis represents the critical dimension of the respective first portion 310A. In some embodiments, a critical dimension SD0 is formed at a position PT1, a critical dimension SD1 is formed at a position PT2, and a critical dimension SD0′ is formed at a position PT3. The critical dimension SD1 may be greater than the critical dimension SD0 (or SD0′). The critical dimension SD0 and the critical dimension SD0′ may (or may not) be equal.

With continued reference to FIG. 5B and FIG. 4B, for the position PT1, the critical dimension SD0 of the first portion 310A may be measured along the Y-direction and between a left edge of the lower side C2 of the pixel region 103-1 and a left edge of the upper side C2 of the pixel region 103-3, in the top plan view. For the position PT2, the critical dimension SD1 of the first portion 310A may be measured along the Y-direction and between a center of the lower side C2 of the pixel region 103-1 and a center of the upper side C2 of the pixel region 103-3, in the top plan view. For the position PT3, the critical dimension SD0′ of the first portion 310A may be measured along the Y-direction and between a right edge of the lower side C2 of the pixel region 103-1 and a right edge of the upper side C2 of the pixel region 103-3, in the top plan view. For example, the maximum critical dimension (e.g., SD1) may be formed in proximity to the position PT2 that is near the center region of the respective first trench TH1. The minimum critical dimension (e.g., SD0 or SD0′) may be formed in proximity to the position (e.g., PT1 or PT3) that is near the edge of the respective first portion 310A formed in the first trench TH1. The critical dimension at the center region greater than at the edge region may result from the pixel region having a concave curved side C2.

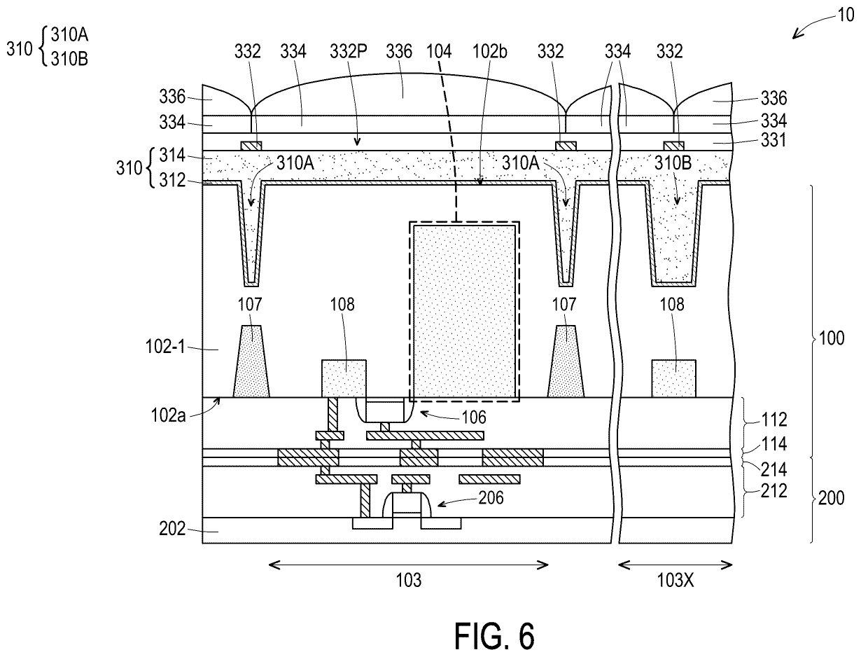

Referring to FIG. 6 and with reference to FIG. 5A, a dielectric layer 331 is optionally formed over the back side 102b of the substrate 102-1. A grid structure 332 is optionally formed on the first portion 310A and the second portion 310B of the BDTI structure 310 and may be embedded in the dielectric layer 331. The dielectric layer 331 may include one or more passivation material(s) or any suitable dielectric material(s). The opening 332P of the grid structure 332 may be formed above the photodetector 104 to enable incident light to pass through the grid structure 332 and to the photodetector 104. The grid structure 332 may include suitable one or more light-shielding material(s) such as metallic material(s) or the like. In some embodiments, light filter regions 334 are formed over the dielectric layer 331 and correspond to the opening 332P of the grid structure 332. For example, the respective light filter region 334 is disposed directly above the opening 332P of the grid structure 332. In some embodiments, micro-lenses 336 are disposed over the light filter regions 334 and configured to focus incident light towards the photodetector 104.

As shown in FIG. 6, an image sensor device 10 is provided. During operation of the image sensor device 10, the incident radiation (not shown) may be focused by the micro-lens 336 to the underlying pixel region in which the photodetector 104 are located. When incident radiation of sufficient energy strikes the photodetector 104, it may generate an electron-hole pair that produces a photocurrent. Notably, FIG. 6 is provided as an example and other examples may differ from what is described with regard to FIG. 6.

The present disclosure relates to an image sensor device including the BDTI structure and an associated method of formation. For example, the critical dimension of the trench for BDTI structure formed in the cross-road region is reduced by the design changes to the patterned mask (e.g., 50A or 50B). The trench depth in the region of the image sensor device with large critical dimension (e.g., in the cross-road region 103X) may be reduced, which prevents trench loading. As a result, the floating diffusion region 108, associated with the photodetector of the image sensor device, may not be damaged during the formation of the trench for the BDTI structure. Reduced chances of damage to the floating diffusion region 108 may improve performance of the image sensor device and may prevent electrical shorts and white pixel defects. The wafer-to-wafer effects (e.g., macro-loading effects) and the within-wafer effects (e.g., micro-loading effects) may be reduced to achieve within-in-wafer and wafer-to-wafer critical dimension uniformity.

In accordance with some embodiments, an image sensor device includes a substrate, photodetectors, and a BDTI structure. The substrate includes a front side, a back side opposite to the front side, and pixel regions disposed between the front side and the back side and arranged in an array. One of the pixel regions includes an angular corner protruding toward a diagonal one of the pixel regions in a top plan view. The photodetectors are disposed in the pixel regions, and the BDTI structure extends from the back side of the substrate and surrounding the respective pixel region.

In accordance with some embodiments, a manufacturing method of an image sensor device includes: forming photodetectors in pixel regions of a substrate, wherein the pixel regions are arranged in an array; forming a patterned mask on a back side of the substrate, where the patterned mask comprises first openings formed over the pixel region and a second opening formed over a cross-road region, and the cross-road region is between one of the pixel regions and a diagonal one of the pixel regions; patterning the substrate using the patterned mask to form first trenches underlying the first openings of the patterned mask and a second trench underlying the second opening of the patterned mask, where the one of the pixel regions comprises an angular corner protruding toward the cross-road region in a top plan view; and filling the first and second trenches to form a BDTI structure.

In accordance with some embodiments, a manufacturing method of an image sensor device includes: forming a patterned mask over a substrate to cover pixel regions within which photodetectors are formed, where the patterned mask includes first openings and a second opening, the first opening exposes an area of the substrate corresponding to a boundary of the respective pixel region, and the second opening exposes another area of the substrate corresponding to a cross-road region disposed among at least four of the pixel regions; removing portions of the substrate exposed by the first openings and the second opening of the patterned mask to respectively form first trenches and a second trench; and forming first portions of a BDTI structure in the first trenches and a second portion of the BDTI structure in the second trench, where in a top plan view, a ratio of a diagonal dimension of the second portion to a critical dimension of the respective first portion is less than 2.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor device, comprising:
a substrate comprising a front side, a back side opposite to the front side, and pixel regions disposed between the front side and the back side and arranged in an array, wherein one of the pixel regions comprises an angular corner protruding toward a diagonal one of the pixel regions in a top plan view;
photodetectors disposed in the pixel regions; and
a backside deep trench isolation (BDTI) structure extending from the back side of the substrate and surrounding the respective pixel region.

2. The image sensor device of claim 1, wherein the one of the pixel region further comprises a concave side connected to the angular corner.

3. The image sensor device of claim 1, further comprising:
a shallow trench isolation (STI) structure extending from the front side of the substrate, wherein the BDTI structure comprises a first portion disposed at a boundary of the respective pixel region and extending toward the STI structure.

4. The image sensor device of claim 3, wherein in the top plan view, a critical dimension of the first portion of the BDTI structure increases from a position corresponding to an edge region of a side of the one of the pixel regions to another position corresponding to a center region of the side of the one of the pixel regions.

5. The image sensor device of claim 3, wherein the first portion of the BDTI structure and the STI structure are tapered in opposing directions.

6. The image sensor device of claim 3, wherein the BDTI structure further comprises a second portion disposed in a cross-road region of the substrate, wherein the cross-road region is between the one of the pixel regions and the diagonal one of the pixel regions.

7. The image sensor device of claim 6, wherein a second maximum critical dimension of the second portion of the BDTI structure is greater than a first maximum critical dimension of the first portion of the BDTI structure.

8. The image sensor device of claim 7, wherein a ratio of the second maximum critical dimension to the first maximum critical dimension is less than 2.

9. The image sensor device of claim 6, wherein the second portion of the BDTI structure is disposed directly over a floating diffusion region disposed at the front side of the substrate.

10. A manufacturing method of an image sensor device, comprising:
forming photodetectors in pixel regions of a substrate, wherein the pixel regions are arranged in an array;
forming a patterned mask on a back side of the substrate, wherein the patterned mask comprises first openings formed over the pixel region and a second opening formed over a cross-road region, and the cross-road region is between one of the pixel regions and a diagonal one of the pixel regions;
patterning the substrate using the patterned mask to form first trenches underlying the first openings of the patterned mask and a second trench underlying the second opening of the patterned mask, wherein the one of the pixel regions comprises an angular corner protruding toward the cross-road region in a top plan view; and
filling the first and second trenches to form a BDTI structure.

11. The manufacturing method of claim 10, wherein:
the patterned mask comprises a masking portion covering the respective pixel region and an assist portion diagonally extending from the masking portion toward the cross-road region in the top plan view, and
after patterning the substrate using the patterned mask, the angular corner of the one of the pixel regions corresponds to the assist portion of the patterned mask.

12. The manufacturing method of claim 10, wherein:
the patterned mask comprises a first layer comprising the first openings and the second opening and a second layer lining each of the first openings and the second opening, and
first portions of the second layer lining the first openings are thinner than a second portion of the second layer lining the second opening.

13. The manufacturing method of claim 12, wherein:
when patterning the substrate using the patterned mask, horizontal segments of the first portions and the second portion overlying the back side of the substrate are removed, and then portions of the substrate underlying the horizontal segments are removed.

14. The manufacturing method of claim 10, wherein:
after patterning the substrate using the patterned mask, the one of the pixel region further comprises a concave side connected to the angular corner.

15. The manufacturing method of claim 10, wherein:
after filling the first and second trenches to form the BDTI structure, a critical dimension of a first portion of the BDTI structure formed in the respective first trench increases from a position corresponding to an edge region of a side of the one of the pixel regions to another position corresponding to a center region of the side of the one of the pixel regions.

16. A manufacturing method of an image sensor device, comprising:
forming a patterned mask over a substrate to cover pixel regions within which photodetectors are formed, wherein:
the patterned mask comprises first openings and a second opening,
the first opening exposes an area of the substrate corresponding to a boundary of the respective pixel region, and
the second opening exposes another area of the substrate corresponding to a cross-road region disposed among at least four of the pixel regions;
removing portions of the substrate exposed by the first openings and the second opening of the patterned mask to respectively form first trenches and a second trench; and
forming first portions of a BDTI structure in the first trenches and a second portion of the BDTI structure in the second trench, wherein in a top plan view, a ratio of a diagonal dimension of the second portion to a critical dimension of the respective first portion is less than 2.

17. The manufacturing method of claim 16, wherein the patterned mask comprises a masking portion and a protrusion diagonally extending from the masking portion toward the cross-road region in the top plan view.

18. The manufacturing method of claim 16, wherein the patterned mask comprises a liner lining each of the first openings and the second openings, a portion of the liner lining the second opening is thicker than another portion of the liner lining the respective first opening.

19. The manufacturing method of claim 16, wherein after removing the portions of the substrate, the respective pixel region of the substrate is formed to have outwardly-protruding corners in the top plan view.

20. The manufacturing method of claim 16, wherein after forming the BDTI structure, the second portion of the BDTI structure is formed over a floating diffusion region disposed at a front side of the substrate.
